(19) United States
(12) Patent Application Publication
(10) Pub. No.: US 2024/0266283 A1
(43) Pub. Date: Aug. 8, 2024

(54) MULTILAYER-TYPE ON-CHIP INDUCTOR STRUCTURE

(71) Applicant: VIA LABS, INC., New Taipei City (TW)

(72) Inventor: Sheng-Yuan LEE, New Taipei City (TW)

(21) Appl. No.: 18/185,500

(22) Filed: Mar. 17, 2023

(30) Foreign Application Priority Data
Feb. 2, 2023 (TW) 112103583

(51) Int. Cl. H01L 23/522; H01F 17/00; H01L 23/528

(52) U.S. Cl. CPC H01L 23/5227; H01F 17/0013; H01L 23/5226; H01L 23/5283; H01F 2017/0073

(57) ABSTRACT

A multilayer-type on-chip inductor structure includes an inter-metal dielectric (IMD) layer having an inductor central region, a first metal winding portion disposed in the IMD layer, and a second metal winding portion disposed in the IMD layer and electrically connected to the overlying first metal winding portion. The first metal winding portion includes a first spiral-type coil surrounding the inductor central region and a first open ring-type coil surrounding the first spiral-type coil. The second metal winding portion includes a second spiral-type coil vertically overlapping the first spiral-type coil and the first open ring-type coil, so that the outermost-turn coil of the second spiral-type coil corresponds to the first open ring-type coil.

### CROSS REFERENCE TO RELATED APPLICATIONS

This application claims priority of Taiwan Patent Application No. 112103583, filed on Feb. 2, 2023, the entirety of which is incorporated by reference herein.

### BACKGROUND OF THE INVENTION

### Field of the Invention

The invention relates to a semiconductor structure, and in particular to a multilayer-type on-chip inductor structure that is capable of reducing the planar size of the inductor structure.

### Description of the Related Art

Many digital/analog devices and circuits have been successfully applied to semiconductor integrated circuits. Such devices may include passive components, such as resistors, capacitors, and inductors. Typically, a semiconductor integrated circuit includes a silicon substrate. One or more dielectric layers are disposed on the substrate, with one or more metal layers disposed in the dielectric layers. The metal layers may be employed to form on-chip elements, such as on-chip inductors, by current semiconductor technologies.

In such on-chip inductors, there are problems with the use of multiple metal layers in the dielectric layer as a spiral-type coil, such as a reduced quality factor (Q value) due to it having less thickness. Furthermore, the inductance of the inductor is usually proportional to the length of the spiral-type coil. Therefore, in order to achieve the desired inductance, the planar size of the inductor and the manufacturing cost both must be increased.

Accordingly, there is a need for a novel inductor structure that is capable of addressing or improving the aforementioned problems.

### BRIEF SUMMARY OF THE INVENTION

In some embodiments, a multilayer-type on-chip inductor structure is provided. The multilayer-type on-chip inductor structure includes an inter-metal dielectric (IMD) layer having an inductor central region, a first metal winding portion disposed in the IMD layer, and a second metal winding portion disposed in the IMD layer and electrically connected to the overlying first metal winding portion. The first metal winding portion includes a first spiral-type coil surrounding the inductor central region and a first open ring-type coil surrounding the first spiral-type coil. The second metal winding portion includes a second spiral-type coil vertically overlapping the first spiral-type coil and the first open ring-type coil, so that the outermost-turn coil of the second spiral-type coil corresponds to the first open ring-type coil.

In some embodiments, a multilayer-type on-chip inductor structure is provided. The multilayer-type on-chip inductor structure includes an IMD layer having an inductor central region, a topmost metal layer disposed in the IMD layer, a next-topmost metal layer disposed in the IMD layer, and a first via-structure region, a second via-structure region, and a third via-structure region disposed between the topmost metal layer and the next-topmost metal layer and electrically connected thereto. The topmost metal layer includes a first double-turn spiral-type coil surrounding the inductor central region and a first single-turn open ring-type coil surrounding the first double-turn spiral-type coil. The next-topmost metal layer includes a second single-turn open ring-type coil surrounding the inductor central region and vertically overlapping the inner-turn coil of the first double-turn spiral-type coil, and a second double-turn spiral-type coil surrounding the second single-turn open ring-type coil. The first single-turn open ring-type coil vertically overlaps the outer-turn of the second double-turn spiral-type coil.

In some embodiments, a multilayer-type on-chip inductor structure is provided. The multilayer-type on-chip inductor structure includes an IMD layer having an inductor central region, a topmost metal layer disposed in the IMD layer, and a next-topmost metal layer disposed in the IMD layer. The topmost metal layer includes a single-turn spiral-type coil surrounding the inductor central region and a single-turn open ring-type coil surrounding the single-turn spiral-type coil. The next-topmost metal layer includes a double-turn spiral-type coil surrounding the inductor central region. The single-turn spiral-type coil vertically overlaps the inner-turn coil of the double-turn spiral-type coil, and the single-turn open ring-type coil vertically overlaps the outer-turn coil of the double-turn spiral-type coil. The multilayer-type on-chip inductor structure also includes a first via-structure region and a second via-structure region. The first via-structure region is electrically connected to a first end portion of the single-turn open ring-type coil and the end portion of the outer-turn coil of the double-turn spiral-type coil. The second via-structure region is electrically connected to a first end portion of the single-turn spiral-type coil and the end portion of the inner-turn coil of the double-turn spiral-type coil.

### BRIEF DESCRIPTION OF THE DRAWINGS

The present invention can be more fully understood by reading the subsequent detailed description and examples with references made to the accompanying drawings, wherein:

FIG. 1 is a plan view of a multilayer-type on-chip inductor structure in accordance with some embodiments of the present disclosure.

FIG. 2 is a cross-sectional view of a semiconductor circuit having the multilayer-type on-chip inductor structure shown in FIG. 1 in accordance with some embodiments of the present disclosure.

FIG. 3A is a plan view of the first metal winding portion of the multilayer-type on-chip inductor structure shown in FIG. 1 in accordance with some embodiments of the present disclosure.

FIG. 3B is a plan view of the second metal winding portion of the multilayer-type on-chip inductor structure shown in FIG. 1 in accordance with some embodiments of the present disclosure.

FIG. 3C is a plan view of the arrangement of the first and second metal winding portions in FIGS. 3A and 3B in accordance with some embodiments of the present disclosure.

FIG. 4 is a plan view of a multilayer-type on-chip inductor structure in accordance with some embodiments of the present disclosure.

FIG. 5 is a cross-sectional view of a semiconductor circuit having the multilayer-type on-chip inductor structure shown in FIG. 4 in accordance with some embodiments of the present disclosure.

FIG. 6A is a plan view of the first metal winding portion of the multilayer-type on-chip inductor structure shown in FIG. 4 in accordance with some embodiments of the present disclosure.

FIG. 6B is a plan view of the second metal winding portion of the multilayer-type on-chip inductor structure shown in FIG. 4 in accordance with some embodiments of the present disclosure.

FIG. 6C is a plan view of the arrangement of the first and second metal winding portions shown in FIGS. 6A and 6B in accordance with some embodiments of the present disclosure.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

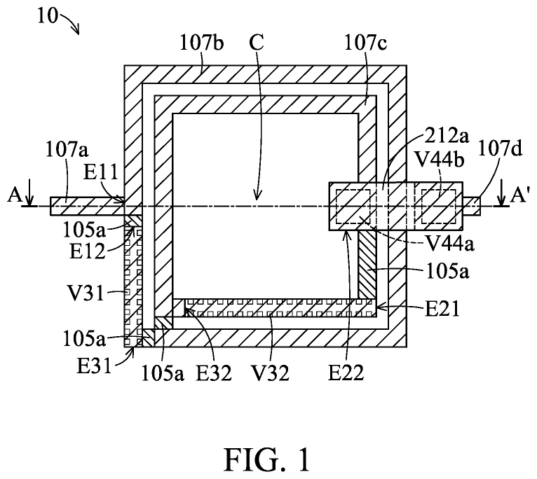

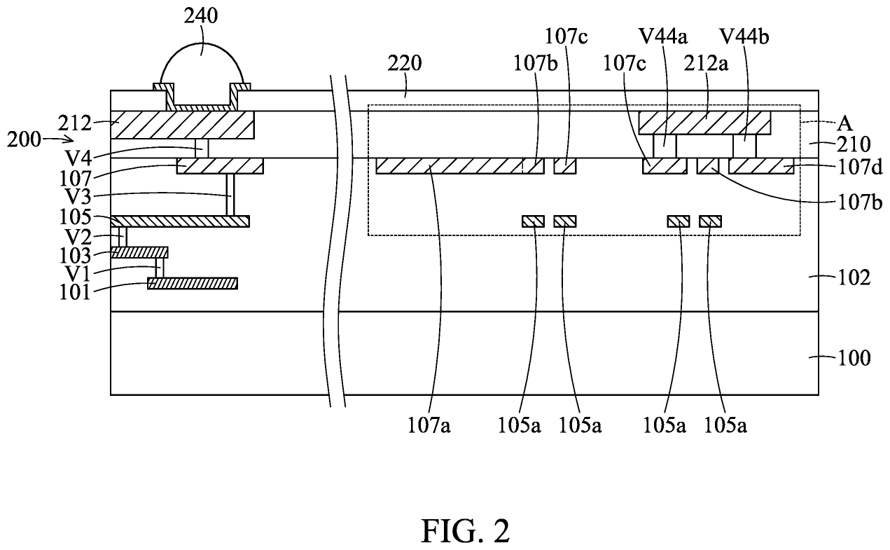

Refer to FIGS. 1 and 2, in which FIG. 1 is a plan view of a multilayer-type on-chip inductor structure 10 in accordance with some embodiments of the present disclosure, and FIG. 2 is a cross-sectional view of a semiconductor circuit having the multilayer-type on-chip inductor structure shown in FIG. 1 in accordance with some embodiments of the present disclosure. The area A (indicated by a dotted-line) in FIG. 2 is a cross-sectional view along the line A-A′ shown in FIG. 1. In some embodiments, the semiconductor circuit includes a substrate 100, an inter-metal dielectric (IMD) layer 102 disposed on the substrate 100, an insulating redistribution layer 210 disposed on the IMD layer 102, vertical and horizontal conductive features and the multilayer-type on-chip inductor structure 10 disposed in the IMD layer 102 and the insulating redistribution layer 210, a passivation layer 220 covering the insulating redistribution layer 210 and connectors 240 (e.g., solder bumps or solder balls) disposed in the passivation layer 220, as shown in FIG. 2.

In some embodiments, the substrate 100 includes a silicon substrate or other conventional semiconductor material substrates. The substrate 100 may include various elements, such as transistors, resistors, capacitors and other conventional semiconductor elements. Moreover, the substrate 100 may also include other conductive layers (e.g., copper, aluminum, or an alloy thereof) and one or more insulating layers (e.g., a silicon oxide layer, a silicon nitride layer, or a low-k dielectric material layer). Herein, in order to simplify the diagram, only a flat substrate is depicted.

In some embodiments, the IMD layer 102 is a single layer of dielectric material or a multilayer dielectric structure. For example, the IMD layer 102 may include multiple layers of dielectric material, which are sequentially formed on the substrate 100 and are alternately with horizontal conductive features (e.g., wiring layers 101, 103, 105 and 107). Herein, in order to simplify the diagram, the IMD layer 102 is depicted as a flat substrate only. The wiring layers 101, 103, 105, and 107 are electrically connected to each other via the vertical conductive features (e.g., conductive plugs V1, V2, and V3), and form an interconnect structure with the IMD layer 102, so as to electrically connect various components disposed on the substrate 100. In some embodiments, the IMD layer 102 may include a silicon oxide layer, a silicon nitride layer, a low-k dielectric material layer or another suitable dielectric material layer.

In some embodiments, the insulating redistribution layer 210 is a single layer of dielectric material or a multilayer dielectric structure. For example, the insulating redistribution layer 210 may include a single layer of dielectric material with a redistribution structure 200 (that is formed of a redistribution layer 212 and at least one conductive plug V4) therein. The connectors 240 are electrically connected to the interconnect structure in the IMD layer 102 through the redistribution layer 212 and the conductive plug V4 in the insulating redistribution layer 210, so that the elements in the substrate 10 are electrically connected to the connectors 240. In some embodiments, the insulating redistribution layer 210 may include an inorganic dielectric layer (e.g., a silicon oxide layer, a silicon nitride layer, or a low-k dielectric material layer), an organic dielectric layer (e.g., polyimide (PI)) or other suitable dielectric material layers.

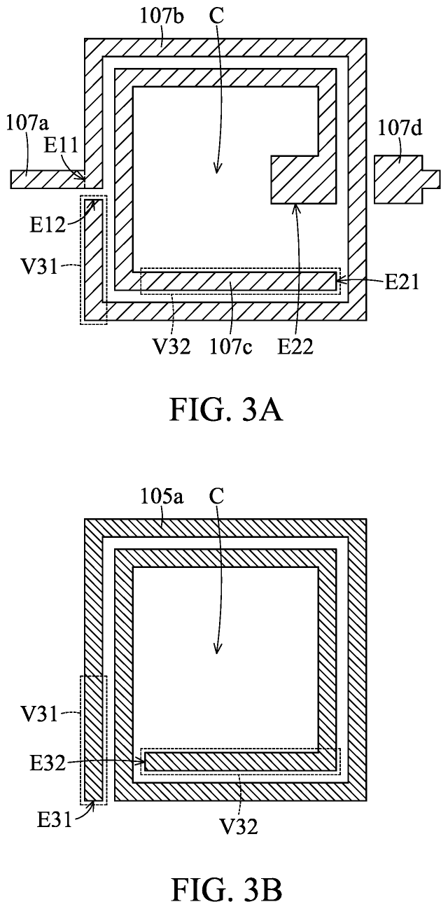

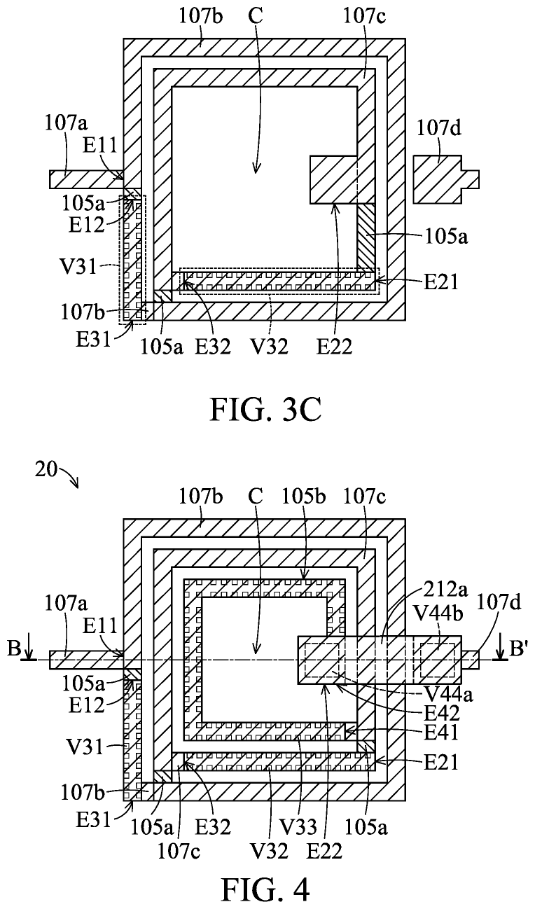

In some embodiments, the multilayer-type on-chip inductor structure 10 includes an IMD layer 102, an insulating redistribution layer 210 disposed on the IMD layer 102, a first metal winding portion (as shown in FIG. 3A) and a second metal winding portion (as shown in FIG. 3B) in the IMD layer 102 in the IMD layer 102, and the conductive cross-connection layer 212a (as shown in FIG. 1) in the insulating redistribution layer 210, as shown in FIG. 2. In some embodiments, the first metal winding portion and the second metal winding portion each have substantially circular, rectangular, hexagonal, octagonal, or polygonal shapes. Herein, in order to simplify the diagram, a rectangle shape is depicted as an example for illustration. Moreover, the first metal winding portion and the second metal winding portion surround an inductor central region C of the IMD layer 102 (as shown in FIG. 1).

In some embodiments, the first metal winding portion and the second metal winding portion are formed by horizontal conductive features in the IMD layer 102, and the conductive cross-connection layer 212a is formed by the horizontal conductive feature in the insulating redistribution layer 210. Each of the first metal winding portion and the second metal winding portion includes at least one coil. In some embodiments, these coils have the same line width and/or pitch.

Refer to FIGS. 1, 2 and 3A, in which FIG. 3A is a plan view of the first metal winding portion of the multilayer-type on-chip inductor structure 10 shown in FIG. 1 in accordance with some embodiments of the present disclosure. In some embodiments, the first metal winding portion includes a first output/input portion 107a, a first open ring-type coil 107b, a first spiral-type coil 107c, and a second output/input portion 107d. Herein, the term “open ring-type coil” refers to a “C” shaped coil. Moreover, the wiring layer 107 and the first metal winding portion (which includes the first output/input portion 107a, the first open ring-type coil 107b, the first spiral-type coil 107c, and a second output/input portion 107d) are disposed at the same lever in the IMD layer 102. For example, the wiring layer 107 and the first metal winding portion may be defined by the topmost metal layer in the IMD layer 102.

In some embodiments, the first spiral-type coil 107c is a single-turn spiral-type coil and surrounds the inductor central region C. Moreover, the first open ring-type coil 107b is also a single-turn spiral-type coil and surrounds the first spiral-type coil 107c. In addition, the first output/input portion 107a and the second output/input portion 107d are disposed in the IMD layer 102 outside the first open ring-type coil 107b. The first output/input portion 107a extends to an end portion E11 of the first open ring-type coil 107b, and the second output/input portion 107d is physically separated from the first open ring-type coil 107b by the IMD layer 102.

In some embodiments, the materials of the first output/input portion 107a, the first open ring-type coil 107b, the first spiral-type coil 107c and the second output/input portion 107d include copper, aluminum, alloys thereof or other suitable metallic materials.

Refer to FIGS. 1, 2 and 3B, in which FIG. 3B is a plan view of the second metal winding portion of the multilayer-type on-chip inductor structure 10 shown in FIG. 1 in accordance with some embodiments of the present disclosure. In some embodiments, the second metal winding portion is disposed in the IMD layer 102 and is electrically connected to the overlying first metal winding portion. The second metal winding portion includes a second spiral-type coil 105a. The second spiral-type coil 105a is a multi-turn spiral-type coil (e.g., a double-turn spiral-type coil) and corresponds to the first open ring-type coil 107b and the first spiral-type coil 107c. Moreover, the wiring layer 105 and the second spiral-type coil 105a are disposed at the same level in the IMD layer 102. For example, the wiring layer 105 and the second spiral-type coil 105a may be defined by the next-topmost metal layer in the IMD layer 102.

In some embodiments, the first spiral-type coil 107c and the second spiral-type coil 105a are spiral-type coils with a different number of turns. For example, the first spiral-type coil 107c is a single-turn spiral-type coil, the second spiral-type coil 105a is a double-turn spiral-type coil, and they surround the inductor central region C. In some embodiments, the material of the second spiral-type coil 105a is the same as or different from that of the first metal winding portion. For example, the second spiral-type coil 105a may be made of copper, aluminum, its alloys or other suitable metal materials.

In some embodiments, the second spiral-type coil 105a vertically overlaps the first open ring-type coil 107b and the first spiral-type coil 107c, so that the outer-turn of the second spiral-type coil 105a (which is double-turn spiral-type coil) corresponds to the first open ring-type coil 107b. As shown in FIG. 3C, the first spiral-type coil 107c (which is single-turn spiral-type coil) vertically overlaps the inner-turn coil of the second spiral-type coil 105a (i.e., double-turn spiral-type coil), and the first spiral-type coil 107c vertically overlaps the outer-turn of the second spiral-type coil 105a.

In some embodiments, the multilayer-type on-chip inductor structure 10 further includes via-structure regions V31 and V32, as shown in FIG. 3C. The via-structure regions V31 and V32 each include conductive plugs (i.e., vertical conductive features in the IMD layer 102). The material and structure of these conductive plugs are similar to those of the conductive plug V3 (shown in FIG. 2), and are disposed in the IMD layer 102.

In some embodiments, the via-structure region V31 is arranged between the first open ring-type coil 107b and the outer-turn coil of the second spiral-type coil 105a, so that the first open ring-type coil 107b is electrically connected to the second spiral-type coil 105a. For example, the via-structure region V31 is electrically connected to the end portion E12 of the first open ring-type coil 107b (which is single-turn open ring-type coil) and the end portion E31 of the second spiral-type coil 105a (which is double-turn spiral-type coil). Moreover, as viewed from a top-view perspective, the via-structure region V31 is disposed between the end portion E12 of the first open ring-type coil 107b and the end portion E31 of the second spiral-type coil 105a.

In some embodiments, the via-structure region V32 is arranged between the first spiral-type coil 107c and the inner-turn coil of the second spiral-type coil 105a, so that the first spiral-type coil 107c is electrically connected to the second spiral-type coil 105a. For example, the via-structure region V32 is electrically connected to the end portion E21 of the first spiral-type coil 107c (which is single-turn spiral-type coil) and the end portion E32 of the inner-turn coil of the second spiral-type coil 105a (which is double-turn spiral-type coil). Moreover, as viewed from a top-view perspective, the via-structure region V32 is disposed between the end portion E21 of the first spiral-type coil 107c and the end portion E32 of the second spiral-type coil 105a.

In some embodiments, as shown in FIGS. 1 and 2, the conductive cross-connection layer 212a disposed in the insulating redistribution layer 210 is electrically connected to the second output/input portion 107d and the end portion E22 of the first spiral-type coil 107c (i.e., single-turn spiral-type coil). The conductive cross-connection layer 212a and the redistribution layer 212 are disposed at the same level in the insulating redistribution layer 210. For example, the conductive cross-connection layer 212a and the redistribution layer 212 may be defined by the topmost metal layer in the redistribution structure 200.

In some embodiments, the multilayer-type on-chip inductor structure 10 further includes via-structure regions V44a and V44b, as shown in FIGS. 1 and 2. Each of the via-structure regions V44a and V44b includes one or more conductive plugs (for example, a single conductive plug). The material and structure of these conductive plugs are similar to those of the conductive plug V4 (shown in FIG. 2), and these conductive plugs are disposed in the insulating redistribution layer 210. In some embodiments, the via-structure region V44a is disposed between the conductive cross-connection layer 212a and the end portion E22 of the first spiral-type coil 107c (i.e., single-turn spiral-type coil). Moreover, the via-structure region V44b is disposed between the conductive cross-connection layer 212a and the second output/input portion 107d.

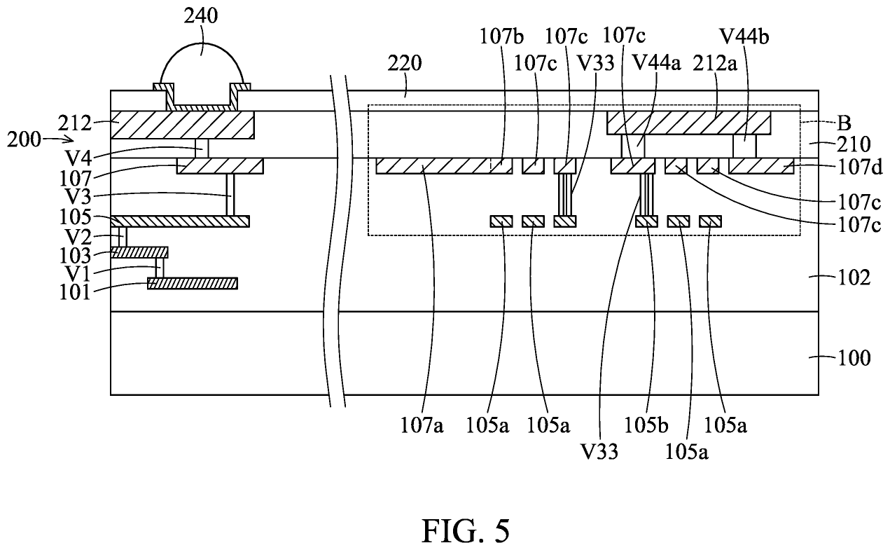

Refer to FIGS. 4 and 5, in which FIG. 4 is a plan view of a multilayer-type on-chip inductor structure 20 in accordance with some embodiments of the present disclosure, and FIG. 5 is a cross-sectional view of a semiconductor circuit having the multilayer-type on-chip inductor structure 20 shown in FIG. 4 in accordance with some embodiments of the present disclosure. The area B (indicated by a dotted-line) in FIG. 5 is a cross-sectional view along the line B-B′ shown in FIG. 4. Herein, elements that are the same as or similar to those of the multilayer-type on-chip inductor structure 10 in FIGS. 1 and 2 are labeled with the same or similar reference numbers as in FIGS. 1 and 2 and are not described again. In some embodiments, the multilayer-type on-chip inductor structure 20 shown in FIGS. 4 and 5 has a structure similar to the multilayer-type on-chip inductor structure 10 in FIGS. 1 and 2. Moreover, the semiconductor circuit shown in FIG. 5 is also the same or similar to the semiconductor circuit shown in FIG. 2.

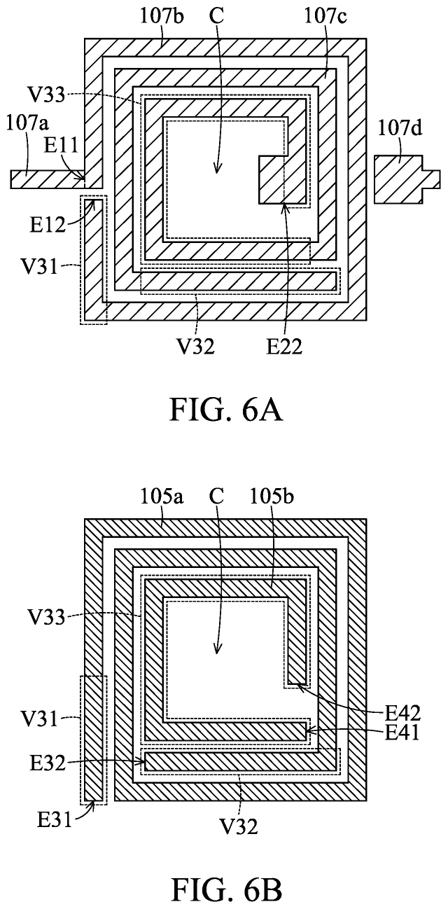

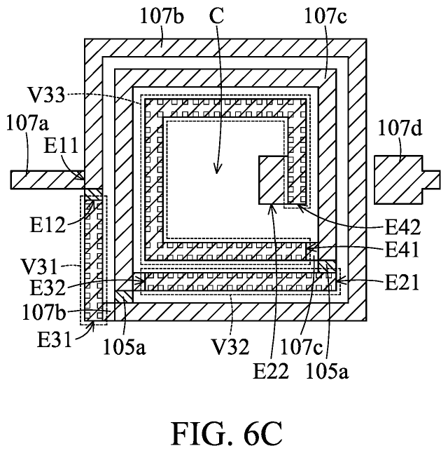

In some embodiments, as shown in FIG. 5, the multilayer-type on-chip inductor structure 20 includes an IMD layer 102, an insulating redistribution layer 210 disposed on the IMD layer 102, the first metal winding portion (as shown in FIG. 6A) and the second metal winding portion (as shown in FIG. 6B) in the IMD layer 102, and a conductive cross-connection layer 212a in the insulating redistribution layer 210 (as shown in FIG. 4). In some embodiments, the first metal winding portion and the second metal winding portion each have substantially circular, rectangular, hexagonal, octagonal, or polygonal shapes. Herein, in order to simplify the diagrams, a rectangle shape is depicted as an example for illustration. Moreover, the first metal winding portion and the second metal winding portion surround an inductor central region C (as shown in FIG. 4) of the IMD layer 102, and each includes at least one coil. In some embodiments, these coils have the same line width and/or pitch.

Refer to FIGS. 4, 5 and 6A, in which FIG. 6A is a plan view of the first metal winding portion of the multilayer-type on-chip inductor structure 20 shown in FIG. 4. In some embodiments, the first metal winding portion includes a first output/input portion 107a, a first open ring-type coil 107b, a first spiral-type coil 107c, and a second output/input portion 107d. The wiring layer 107 and the first metal winding portion (including the first output/input portion 107a, the first open ring-type coil 107b, the first spiral-type coil 107c and the second output/input portion 107d) can be defined by the topmost metal layer in the IMD layer 102.

In some embodiments, the first spiral-type coil 107c is a multi-turn spiral-type coil (e.g., a double-turn spiral-type coil or a spiral-type coil with more than three turns), and surrounds the inductor central region C. Moreover, the first open ring-type coil 107b is a single-turn spiral-type coil and surrounds the first spiral-type coil 107c. In addition, the first output/input portion 107a and the second output/input portion 107d are disposed in the IMD layer 102 outside the first open ring-type coil 107b. The first output/input portion 107a extends to an end portion E11 of the first open ring-type coil 107b, and the second output/input portion 107d is physically separated from the first open ring-type coil 107b by the IMD layer 102.

Refer to FIGS. 4, 5 and 6B, in which FIG. 6B is a plan view of the second metal winding portion of the multilayer-type on-chip inductor structure 20 shown in FIG. 4. In some embodiments, the second metal winding portion is disposed in the IMD layer 102 and is electrically connected to the overlying first metal winding portion. The second metal winding portion includes a second spiral-type coil 105a and a second open ring-type coil 105b. The second spiral-type coil 105a is a multi-turn spiral-type coil (e.g., a double-turn spiral-type coil or a spiral-type coil with more than three turns), and surrounds the inductor central region C. Moreover, the second open ring-type coil 105b is a single-turn spiral-type coil and is surrounded by the second spiral-type coil 105a. The second spiral-type coil 105a corresponds to the first open ring-type coil 107b and a portion of the first spiral-type coil 107c, and the second open ring-type coil 105b corresponds to another portion of the first spiral-type coil 107c. Moreover, the wiring layer 105, the second spiral-type coil 105a, and the second open ring-type coil 105b are disposed at the same level in the IMD layer 102. For example, the wiring layer 105, the second spiral-type coil 105a, and the second open ring-type coil 105b may be defined by the next-topmost metal layer in the IMD layer 102.

In some embodiments, the first spiral-type coil 107c and the second spiral-type coil 105a are spiral-type coils with the same number of turns. For example, both are double-turn spiral-type coils. The first open ring-type coil 107b and the second open ring-type coil 105b are also open ring-type coils with the same number of turns. For example, the first open ring-type coil 107b and the second open ring-type coil 105b are both a single-turn open ring-type coil, and surround the inductor central region C.

In some embodiments, as shown in FIG. 6C, the second spiral-type coil 105a (i.e., double-turn spiral-type coil) vertically overlaps the first open ring-type coil 107b and a portion of the first spiral-type coil 107c (i.e., double-turn spiral-type coil), and the second open ring-type coil 105b corresponds to another portion of the first spiral-type coil 107c. As a result, the outermost-turn coil of the second spiral-type coil 105a corresponds to the first open ring-type coil 107b, and the innermost-turn coil of the spiral-type coil 105a corresponds to the outermost-turn coil of the first spiral-type coil 107c. Moreover, the second open ring-type coil 105b (i.e., single-turn open ring-type coil) vertically overlaps the innermost-turn coil of the first spiral-type coil 107c.

In some embodiments, the multilayer-type on-chip inductor structure 20 further includes via-structure regions V31, V32 and V33, as shown in FIG. 6C. As with the via-structure regions V31 and V32, the via-structure region V33 also includes conductive plugs. The material and structure of the via-structure region V33 are also similar to those of conductive plug V3 (shown in FIG. 2), and are disposed in the IMD layer 102.

In some embodiments, the via-structure region V31 is arranged between the first open ring-type coil 107b and the outer-turn coil of the second spiral-type coil 105a, so that the first open ring-type coil 107b is electrically connected to the second spiral-type coil 105a. For example, the via-structure region V31 is electrically connected to an end portion E12 of the first open ring-type coil 107b (i.e., single-turn open ring-type coil) and an end portion E31 of the second spiral-type coil 105a (i.e., double-turn spiral-type coil). Moreover, as viewed from a top-view perspective, the via-structure region V31 is disposed between the end portion E12 of the first open ring-type coil 107b and the end portion E31 of the second spiral-type coil 105a, and is adjacent to the end portion E12 and the end portion E31.

In some embodiments, the via-structure region V32 is disposed between the outer-turn coil of the first spiral-type coil 107c and the inner-turn coil of the second spiral-type coil 105a, so that the first spiral-type coil 107c is electrically connected to the second spiral-type coil 105a. For example, the via-structure region V32 is electrically connected to the end portion E21 of the outer-turn coil of the first spiral-type coil 107c (i.e., double-turn spiral-type coil) and the end portion of the coil is E32 of the inner-turn coil of the second spiral-type coil 105a (i.e., double-turn spiral-type coil). Moreover, as viewed from a top-view perspective, the via-structure region V32 is disposed between the end portion E21 of the first spiral-type coil 107c and the end portion E32 of the second spiral-type coil 105a, and is adjacent to the end portion E21 and the end portion E32.

In some embodiments, the via-structure region V33 is disposed between the inner-turn coil of the first spiral-type coil 107c and the second open ring-type coil 105b, so that the first spiral-type coil 107c is stacked over the second open ring-type coil 105b, and electrically connected thereto. For example, the via-structure region V33 is electrically connected to the inner-turn coil of the first spiral-type coil 107c (i.e., double-turn spiral-type coil), and stacked on and electrically connected to the second open ring-type coil 105b (i.e., single-turn open ring-type coil). Moreover, as viewed from the top-view perspective, the via-structure region V33 is disposed between the end portion E41 of the second open ring-type coil 105b and the end portion E42 of the second open ring-type coil 105b, and is adjacent to the end portion E22 of the first spiral-type coil 107c and the end portions E41 and E42 of the open ring-type coil 105b.

A stacking layer formed by the first spiral-type coil 107c defined by the topmost metal layer in the IMD layer 102 and the second open ring-type coil 105b defined by the next-topmost metal layer in the IMD layer 102 can increase the cross section of the inductor significantly. Here, the term “cross section” refers to an area of the coil stacking layer perpendicular to the current direction in the inductor. As a result, the multilayer-type on-chip inductor structure 20 can reduce the conductor loss of the winding portion due to the thicker coils, thereby improving the Q value and performance of the inductor. As an example shown in FIG. 6C, to achieve an inductance similar to that in FIG. 6C by 12 nm process conditions, and only use the topmost metal layer for designing the multi-turn spiral-type coil, the occupied area is about 27.5 μm×25 μm. In the embodiment of FIG. 6C, however, the occupied area is only about 21 μm×21 μm. Therefore, by defining the second spiral-type coil (and the second open ring-type coil) using the next-topmost metal layer, the occupied area of the inductor can also be reduced.

In some embodiments, as shown in FIGS. 4 and 5, the conductive cross-connection layer 212a disposed in the insulating redistribution layer 210 is electrically connected to the second output/input portion 107d and the end portion E22 of the inner-turn coil of the first spiral-type coil 107c (i.e., double-turn spiral-type coil).

In some embodiments, the multilayer-type on-chip inductor structure 20 further includes via-structure regions V44a and V44b, as shown in FIGS. 4 and 5. Each of via-structure regions V44a and V44b includes one or more conductive plugs (e.g., a single conductive plug). The material and structure of these conductive plugs are similar to those of the conductive plug V4 (shown in FIG. 5), and are disposed in the insulating redistribution layer 210. In some embodiments, the via-structure region V44a is disposed between the conductive cross-connection layer 212a and the end portion E22 of the inner-turn coil of the first spiral-type coil 107c (i.e., double-turn spiral-type coil). Moreover, the via-structure region V44b is disposed between the conductive cross-connection layer 212a and the second output/input portion 107d.

In the multilayer-type on-chip inductor structure according to the foregoing embodiments, the first metal winding portion (including the spiral-type coil and open ring-type coil surrounding the spiral-type coil) of the inductor is formed by the use of the topmost metal layer in the IMD layer. Moreover, the second metal winding portion (including the spiral-type coil or including the open ring-type coil and the spiral-type coil surrounding the open ring-type coil) of the inductor is formed by the use of the next-topmost metal layer in the IMD layer. As a result, compared to the single-layer spiral-type inductor structure, the inductor structure formed by the stack of the first metal winding portion and the second metal winding portion can effectively increase the coil length to obtain the desired inductance value while reducing the occupied area of the inductor. Since the occupied area of the inductor is reduced, the manufacturing cost can be reduced.

In the multilayer-type on-chip inductor structure according to the foregoing embodiments, a stacking layer formed of the spiral-type coil defined by the topmost metal layer in the IMD layer and the open ring-type coil defined by the next-topmost metal layer in the IMD layer can increase the cross section of the inductor significantly. As a result, the conductor loss of the winding portion of the inductor can be reduced, thereby improving the quality factor of the inductor and improving the inductor performance.

In addition, since the multilayer-type on-chip inductor structure can be formed during the fabrication of the interconnect structure and the redistribution structure, there is no need to use additional metal layers and additional processes to fabricate the multilayer-type on-chip inductor structure. As a result, the manufacturing cost will not increase.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A multilayer-type on-chip inductor structure, comprising:
an inter-metal dielectric (IMD) layer having an inductor central region;
a first metal winding portion disposed in the IMD layer, comprising:
a first spiral-type coil surrounding the inductor central region; and
a first open ring-type coil surrounding the first spiral-type coil; and
a second metal winding portion disposed in the IMD layer and electrically connected to the overlying first metal winding portion, comprising:
a second spiral-type coil vertically overlapping the first spiral-type coil and the first open ring-type coil, so that an outermost-turn coil of the second spiral-type coil corresponds to the first open ring-type coil.

2. The structure as claimed in claim 1, further comprising:
a first via-structure region disposed between the first open ring-type coil and the outermost-turn coil of the second spiral-type coil, so that the first open ring-type coil is electrically connected to the second spiral-type coil; and
a second via-structure region disposed between an outermost-turn coil of the first spiral-type coil and an innermost-turn coil of the second spiral-type coil, so that the first spiral-type coil is electrically connected to the second spiral-type coil.

3. The structure as claimed in claim 1, wherein the second metal winding portion further comprises:
a second open ring-type coil vertically overlapping an innermost-turn coil of the first spiral-type coil.

4. The structure as claimed in claim 3, further comprising:
a first via-structure region disposed between the first open ring-type coil and the outermost-turn coil of the second spiral-type coil, so that the first open ring-type coil is electrically connected to the second spiral-type coil;
a second via-structure region disposed between the outermost-turn coil of the first spiral-type coil and the innermost-turn coil of the second spiral-type coil, so that the first spiral-type coil is electrically connected to the second spiral-type coil; and
a third via-structure region disposed between the innermost-turn coil of the first spiral-type coil and the second spiral-type coil, so that the first spiral-type coil is electrically connected to the second open ring-type coil.

5. The structure as claimed in claim 3, wherein the first spiral-type coil and the second spiral-type coil are spiral-type coils with a same number of turns.

6. The structure as claimed in claim 5, further comprising:
a first output/input portion and a second output/input portion disposed in the IMD layer outside the first open ring-type coil,
wherein the first output/input portion extends to an end portion of the first open ring-type coil, and wherein the second output/input portion is physically separated from the first open ring-type coil.

7. The structure as claimed in claim 6, further comprising:
an insulating redistribution layer disposed on the IMD layer; and
a conductive cross-connection layer disposed in the insulating redistribution layer and electrically connected to the second output/input portion and an end portion of an innermost-turn coil of the first spiral-type coil.

8. The structure as claimed in claim 7, further comprising:
a first via-structure region disposed in the insulating redistribution layer and between the conductive cross-connection layer and the second output/input portion; and
a second via-structure region disposed in the insulating redistribution layer and between the conductive cross-connection layer and the end portion of the innermost-turn coil of the first spiral-type coil.

9. The structure as claimed in claim 1, wherein the first metal winding portion is defined by a topmost metal layer in the IMD layer, and the second metal winding portion is defined by a next-topmost metal layer in the IMD layer.

10. The structure as claimed in claim 1, wherein the first spiral-type coil and the second spiral-type coil are spiral-type coils with a different number of turns.

11. A multilayer-type on-chip inductor structure, comprising:
an inter-metal dielectric (IMD) layer having an inductor central region;
a topmost metal layer disposed in the IMD layer, comprising:
a first double-turn spiral-type coil surrounding the inductor central region; and
a first single-turn open ring-type coil surrounding the first double-turn spiral-type coil;
a next-topmost metal layer disposed in the IMD layer, comprising:
a second single-turn open ring-type coil surrounding the inductor central region and vertically overlapping an inner-turn coil of the first double-turn spiral-type coil; and
a second double-turn spiral-type coil surrounding the second single-turn open ring-type coil, wherein the first single-turn open ring-type coil vertically overlaps an outer-turn of the second double-turn spiral-type coil; and
a first via-structure region, a second via-structure region, and a third via-structure region disposed between the topmost metal layer and the next-topmost metal layer and electrically connected thereto.

12. The structure as claimed in claim 11, wherein the topmost metal layer further comprises:
a first output/input portion and a second output/input portion disposed in the IMD layer outside the first single-turn open ring-type coil,
wherein the first output/input portion extends to an end portion of the first single-turn open ring-type coil, and wherein the second output/input portion is physically separated from the first single-turn open ring-type coil.

13. The structure as claimed in claim 12, further comprising:
an insulating redistribution layer disposed on the IMD layer; and
a conductive cross-connection layer disposed in the insulating redistribution layer and electrically connected to the second output/input portion and an end portion of the inner-turn coil of the first double-turn spiral-type coil.

14. The structure as claimed in claim 13, further comprising:
a fourth via-structure region disposed in the insulating redistribution layer and between the conductive cross-connection layer and the second output/input portion; and
a fifth via-structure region disposed in the insulating redistribution layer and between the conductive cross-connection layer and an end portion of the inner-turn coil of the first double-turn spiral-type coil.

15. The structure as claimed in claim 11, wherein:
the first via-structure region is correspondingly disposed above the second double-turn spiral-type coil and adjacent to an end portion of the outer-turn coil of the second double-turn spiral-type coil;
the second via-structure region is correspondingly disposed above the second double-turn spiral-type coil and adjacent to an end portion of an inner-turn coil of the second double-turn spiral-type coil; and
the third via-structure region is correspondingly disposed above the second single-turn open ring-type coil.

16. A multilayer-type on-chip inductor structure, comprising:
an inter-metal dielectric (IMD) layer having an inductor central region;
a topmost metal layer disposed in the IMD layer, comprising:
a single-turn spiral-type coil surrounding the inductor central region; and
a single-turn open ring-type coil surrounding the single-turn spiral-type coil;
a next-topmost metal layer disposed in the IMD layer, comprising:
a double-turn spiral-type coil surrounding the inductor central region, wherein the single-turn spiral-type coil vertically overlaps an inner-turn coil of the double-turn spiral-type coil, and the single-turn open ring-type coil vertically overlaps an outer-turn coil of the double-turn spiral-type coil;
a first via-structure region electrically connected to a first end portion of the single-turn open ring-type coil and the end portion of the outer-turn coil of the double-turn spiral-type coil; and
a second via-structure region electrically connected to a first end portion of the single-turn spiral-type coil and an end portion of the inner-turn coil of the double-turn spiral-type coil.

17. The structure as claimed in claim 16, wherein the topmost metal layer further comprises:
a first output/input portion and a second output/input portion disposed in the IMD layer outside the single-turn open ring-type coil,
wherein the first output/input portion extends to a second end portion of the single-turn spiral-type coil, and wherein the second output/input portion is physically separated from the single-turn spiral-type coil.

18. The structure as claimed in claim 17, further comprising:
an insulating redistribution layer disposed on the IMD layer; and
a conductive cross-connection layer disposed in the insulating redistribution layer and electrically connected to the second output/input portion and a second end portion of the single-turn spiral-type coil.

19. The structure as claimed in claim 18, further comprising:
a third via-structure region disposed in the insulating redistribution layer and between the conductive cross-connection layer and the second output/input portion; and
a fourth via-structure region disposed in the insulating redistribution layer and between the conductive cross-connection layer and the second end portion of the single-turn spiral coil.
